(19) United States
(12) Patent Application Publication
(10) Pub. No.: US 2025/0309869 A1
(43) Pub. Date: Oct. 2, 2025

(54) SEMICONDUCTOR DEVICE AND METHOD FOR CONTROLLING THE SEMICONDUCTOR DEVICE

(71) Applicant: Renesas Electronics Corporation, Tokyo (JP)

(72) Inventor: Ryutaro MINESAWA, Tokyo (JP)

(73) Assignee: Renesas Electronics Corporation, Tokyo (JP)

(21) Appl. No.: 19/089,670

(22) Filed: Mar. 25, 2025

(30) Foreign Application Priority Data
Mar. 28, 2024 (JP) 2024-052954

(51) Int. Cl. H03K 3/012; H02M 7/537; H03K 17/567; H03K 17/687; H10D 84/80

(52) U.S. Cl. CPC H03K 3/012; H02M 7/537; H03K 17/567; H03K 17/687; H10D 84/811

(57) ABSTRACT

A semiconductor device includes a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET, in which the controller controls the first gate in a state where the second gate is turned on.

### CROSS-REFERENCE TO RELATED APPLICATION

The disclosure of Japanese Patent Application No. 2024-052954 filed on Mar. 28, 2024 including the specification, drawings and abstract is incorporated herein by reference in its entirety.

### BACKGROUND

The present disclosure relates to a semiconductor device and a method for controlling a semiconductor device, and for example, relates to a semiconductor device including a metal-oxide-semiconductor field-effect transistor (MOSFET) and an insulated gate bipolar transistor (IGBT), and a method for controlling the semiconductor device.

There are disclosed techniques listed below.
[Patent Document 1] Japanese Unexamined Patent Application Publication No. 2020-102923
Patent Document 1 discloses a method for controlling a semiconductor device including an inverter.

### SUMMARY

It is desired to reduce power loss of a semiconductor device including an inverter and improve efficiency of the inverter.

Other problems and novel features will become apparent from the description of the present specification and the accompanying drawings.

According to one embodiment, a semiconductor device includes a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET, in which the controller controls the first gate in a state where the second gate is turned on.

According to one embodiment, a method for controlling a semiconductor device is a method for controlling a semiconductor device including a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET, the method including a step of controlling the first gate in a state where the second gate is turned on.

According to the embodiments, it is possible to provide a semiconductor device that can improve the efficiency of the inverter and a method for controlling the semiconductor device.

### BRIEF DESCRIPTION OF THE DRAWINGS

FIG. 1 is a circuit diagram illustrating an inverter in a semiconductor device according to a first comparative example.

FIG. 2 is a circuit diagram illustrating an inverter in a semiconductor device according to a second comparative example.

FIG. 3 is a circuit diagram illustrating an inverter in a semiconductor device according to a third comparative example.

FIG. 4 is a graph illustrating a conduction loss of the inverters in the semiconductor devices according to the first to third comparative examples, in which the horizontal axis represents a voltage between a collector terminal and an emitter terminal in an IGBT or a voltage between a drain terminal and a source terminal in a MOSFET, and the vertical axis represents a current between the collector terminal and the emitter terminal in the IGBT or a current between the drain terminal and the source terminal in the MOSFET.

FIG. 5 is a graph illustrating a tail current at the time of turn-off in the semiconductor device according to the first comparative example, in which the horizontal axis represents time and the vertical axis represents a current or a voltage.

FIG. 6 is a graph illustrating a current at the time of turn-off in the semiconductor device according to the second comparative example, in which the horizontal axis represents time and the vertical axis represents a current or a voltage.

FIG. 7 is a graph illustrating a reverse recovery current of an FRD in the semiconductor device according to the first comparative example, in which the horizontal axis represents time and the vertical axis represents a current flowing through the FRD.

FIG. 8 is a graph illustrating a reverse recovery current of an SBD in the semiconductor device according to the third comparative example, in which the horizontal axis represents time and the vertical axis represents a current flowing through the SBD.

FIG. 9 is a circuit diagram illustrating an inverter in a semiconductor device according to a first embodiment.

FIG. 10 is a graph illustrating a conduction loss of the inverter in the semiconductor device according to the first embodiment, in which the horizontal axis represents a voltage between a collector terminal and an emitter terminal in an IGBT or a voltage between a drain terminal and a source terminal in a MOSFET, and the vertical axis represents a current between the collector terminal and the emitter terminal in the IGBT or a current between the drain terminal and the source terminal in the MOSFET.

FIG. 11 is a circuit diagram illustrating the outline of exclusive control of an inverter in a semiconductor device according to the first embodiment.

FIG. 12 is a circuit diagram illustrating the outline of individual control of an inverter in a semiconductor device according to the first embodiment.

FIG. 13 is a circuit diagram illustrating the outline of simultaneous control of an inverter in a semiconductor device according to the first embodiment.

FIG. 14 is a block diagram illustrating a controller in the semiconductor device according to the first embodiment.

FIG. 15 is a block diagram illustrating an MCU in the semiconductor device according to the first embodiment.

FIG. 16 is a block diagram illustrating a GDU in the semiconductor device according to the first embodiment.

FIG. 17 is a flowchart illustrating a control method by the controller in the semiconductor device according to the first embodiment.

FIG. 18 is a graph illustrating changes in a gate voltage V_{G1}, a voltage V_{CE}, and a current I_{CE} of an IGBT, and a gate voltage V_{G2}, a voltage V_{DS}, and a current I_{DS} of a MOSFET in the semiconductor device according to the first embodiment, in which the horizontal axis represents time, and the vertical axis represents each voltage and each current.

FIG. 19 is a flowchart illustrating a control method by the controller in the semiconductor device according to the first embodiment.

FIG. 20 is a graph illustrating changes in the gate voltage V_{G1}, the voltage V_{CE}, and the current I_{CE} of the IGBT, and the gate voltage V_{G2}, the voltage V_{DS}, and the current I_{DS} of the MOSFET in the semiconductor device according to the first embodiment, in which the horizontal axis represents time, and the vertical axis represents each voltage and each current.

FIG. 21 is a circuit diagram illustrating a GDU and an MCU that perform individual control in the semiconductor device according to the first embodiment.

FIG. 22 is a circuit diagram illustrating a GDU and an MCU that perform individual control in a semiconductor device according to a modification of the first embodiment.

FIG. 23 is a circuit diagram illustrating a GDU and an MCU that perform simultaneous control in a semiconductor device according to the first embodiment.

FIG. 24 is a circuit diagram illustrating another GDU and another MCU that perform simultaneous control in a semiconductor device according to a first modification of the first embodiment.

FIG. 25 is a circuit diagram illustrating another GDU and another MCU that perform simultaneous control in a semiconductor device according to a second modification of the first embodiment.

### DETAILED DESCRIPTION

For clarity of description, the following description and drawings are omitted and simplified as appropriate. In the drawings, the same elements are denoted by the same reference numerals, and redundant description is omitted as necessary. In addition, reference numerals are appropriately omitted so as not to complicate the drawings.

First, a semiconductor device according to first to third comparative examples and a method for controlling the semiconductor device will be described in <First Comparative Example> to <Third Comparative Example>. Thereafter, problems the inventor newly found on the first to third comparative examples will be described in <Problems Newly Found by Inventor>. Then, a semiconductor device and a method for controlling the semiconductor device according to an embodiment will be described in <First Embodiment>. Accordingly, the semiconductor device and the method for controlling the semiconductor device according to the embodiment are made clearer. Note that the semiconductor device according to any one of the first to third comparative examples and the method for controlling the semiconductor device, and the problems newly found by the inventor are also within the scope of the technical idea of the embodiment.

### First Comparative Example

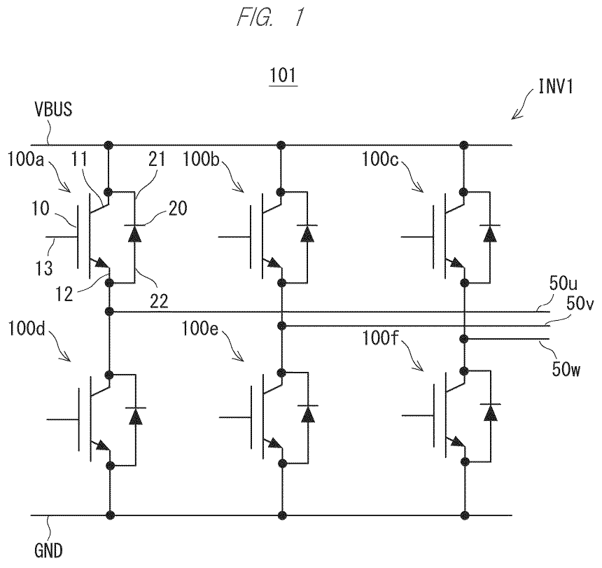

The first comparative example is an example in which an inverter includes an IGBT and a fast recovery diode (FRD). FIG. 1 is a circuit diagram illustrating an inverter INV1 in a semiconductor device 101 according to the first comparative example. In FIG. 1, some reference numerals are omitted not to complicate the drawing. Similarly, some reference numerals may be omitted in the following drawings. As illustrated in FIG. 1, the semiconductor device 101 according to the first comparative example includes the inverter INV1. The semiconductor device 101 includes, for example, a power module to control driving of a motor and the like. The inverter INV1 has a function of performing switching control of a voltage to be applied to the motor. The inverter INV1 applies, for example, a drive voltage of six channels to the motor to cause a current to flow through the motor, thereby driving the motor. The motor may be, for example, a three-phase motor including a u-phase terminal 50u, a v-phase terminal 50v, and a w-phase terminal 50w. The inverter INV1 may include a plurality of semiconductor elements 100a to 100f according to the number of channels.

The semiconductor element 100a is disposed between wiring VBUS, to which a power supply voltage is applied, and the terminal 50u. The semiconductor element 100b is disposed between the wiring VBUS and the terminal 50v. The semiconductor element 100c is disposed between the wiring VBUS and the terminal 50w. On the other hand, the semiconductor element 100d is disposed between wiring GND, to which a ground power supply voltage is applied, and the terminal 50u. The semiconductor element 100e is disposed between the wiring GND and the terminal 50v. The semiconductor element 100f is disposed between the wiring GND and the terminal 50w.

The plurality of semiconductor elements 100a to 100f are collectively referred to as a semiconductor element 100. The semiconductor element 100 includes an IGBT 10 and an FRD 20. In the semiconductor element 100, a collector terminal 11 of the IGBT 10 is connected to a cathode terminal 21 of the FRD 20. An emitter terminal 12 of the IGBT 10 is connected to an anode terminal 22 of the FRD 20. The semiconductor element 100 includes the FRD 20 containing silicon (Si). The FRD 20 described below may contain Si.

In the semiconductor elements 100a to 100c, the collector terminals 11 of the IGBTs 10 and the cathode terminals 21 of the FRDs 20 are connected to the wiring VBUS. In the semiconductor elements 100a to 100c, the emitter terminals 12 of the IGBTs 10 and the anode terminals 22 of the FRDs 20 are connected to the terminals 50u to 50w, respectively. In the semiconductor elements 100d to 100f, the collector terminals 11 of the IGBTs 10 and the cathode terminals 21 of the FRDs 20 are connected to the terminals 50u to 50w, respectively. In the semiconductor elements 100d to 100f, the emitter terminals 12 of the IGBTs 10 and the anode terminals 22 of the FRDs 20 are connected to the wiring GND.

A gate terminal 13 of the IGBT 10 is connected to, for example, a gate driver. The semiconductor element 100 may include a diode such as a freewheeling diode (FWD) instead of the FRD 20.

### Second Comparative Example

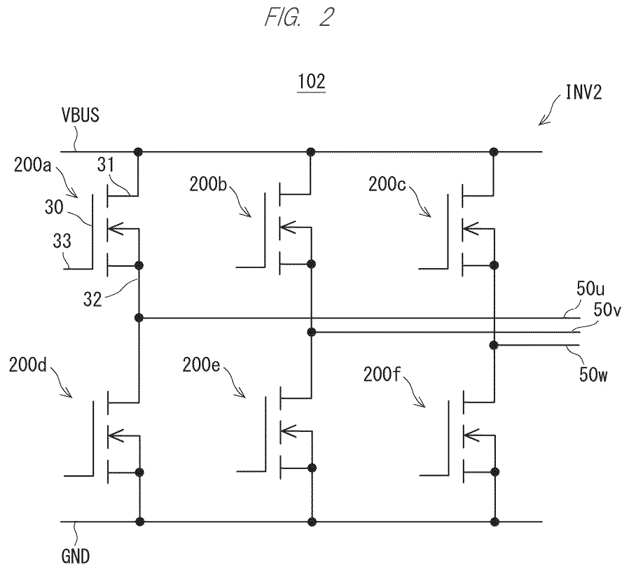

A second comparative example is an example in which an inverter includes a MOSFET. The MOSFET may be formed using silicon carbide (SiC). FIG. 2 is a circuit diagram illustrating an inverter INV2 in a semiconductor device 102 according to the second comparative example. As illustrated in FIG. 2, the semiconductor device 102 according to the second comparative example includes the inverter INV2. The inverter INV2 has the same function as that of the inverter INV1. The inverter INV2 may include a plurality of semiconductor elements 200a to 200f.

The semiconductor element 200a is disposed between the wiring VBUS and the terminal 50u. The semiconductor element 200b is disposed between the wiring VBUS and the terminal 50v. The semiconductor element 200c is disposed between the wiring VBUS and the terminal 50w. On the other hand, the semiconductor element 200d is disposed between the wiring GND and the terminal 50u. The semiconductor element 200e is disposed between the wiring GND and the terminal 50v. The semiconductor element 200f is disposed between the wiring GND and the terminal 50w.

The plurality of semiconductor elements 200a to 200f are collectively referred to as a semiconductor element 200. The semiconductor element 200 includes, for example, a MOSFET 30 containing SiC. The MOSFET 30 described below may contain SiC.

Drain terminals 31 of the MOSFETs 30 in the semiconductor elements 200a to 200c are connected to the wiring VBUS. Source terminals 32 of the MOSFETs 30 in the semiconductor elements 200a to 200c are connected to the terminals 50u to 50w, respectively. Drain terminals 31 of the MOSFETs 30 in the semiconductor elements 200d to 200f are connected to the terminals 50u to 50w, respectively. Source terminals 32 of the MOSFETs 30 in the semiconductor elements 200d to 200f are connected to the wiring GND.

A gate terminal 33 of the MOSFET 30 is connected to, for example, a gate driver. In the semiconductor element 200, an impurity region formed in the MOSFET 30 has a function of an FWD as a diode. That is, in the semiconductor device 102, the body diode of the MOSFET 30 serves as an FWD.

### Third Comparative Example

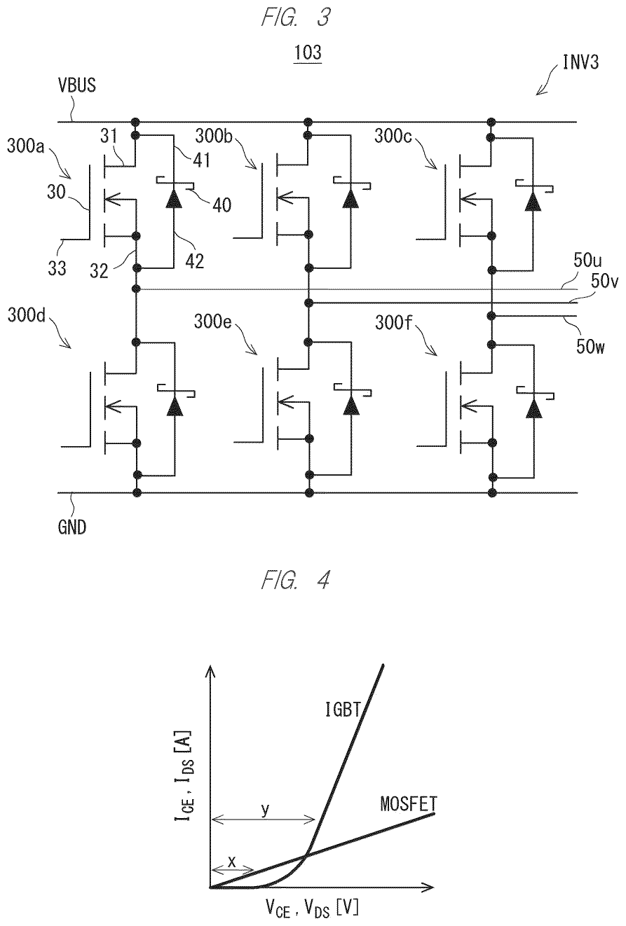

A third comparative example is an example in which an inverter includes a MOSFET and a Schottky barrier diode (SBD). The SBD may be configured as an external component. FIG. 3 is a circuit diagram illustrating an inverter INV3 in a semiconductor device 103 according to the third comparative example. As illustrated in FIG. 3, the semiconductor device 103 according to the third comparative example includes the inverter INV3. The inverter INV3 has the same function as that of the inverter INV1. The inverter INV3 may include a plurality of semiconductor elements 300a to 300f.

The semiconductor element 300a is disposed between the wiring VBUS and the terminal 50u. The semiconductor element 300b is disposed between the wiring VBUS and the terminal 50v. The semiconductor element 300c is disposed between the wiring VBUS and the terminal 50w. On the other hand, the semiconductor element 300d is disposed between the wiring GND and the terminal 50u. The semiconductor element 300e is disposed between the wiring GND and the terminal 50v. The semiconductor element 300f is disposed between the wiring GND and the terminal 50w.

The plurality of semiconductor elements 300a to 300f are collectively referred to as a semiconductor element 300. The semiconductor element 300 may include a MOSFET 30 and an SBD 40. In the semiconductor element 300, a drain terminal 31 of the MOSFET 30 is connected to a cathode terminal 41 of the SBD 40. A source terminal 32 of the MOSFET 30 is connected to an anode terminal 42 of the SBD 40.

In the semiconductor elements 300a to 300c, the drain terminals 31 of the MOSFETs 30 and the cathode terminals 41 of the SBDs 40 are connected to the wiring VBUS. In the semiconductor elements 300a to 300c, the source terminals 32 of the MOSFETs 30 and the anode terminals 42 of the SBDs 40 are connected to the terminals 50u to 50w, respectively. In the semiconductor elements 300d to 300f, the drain terminals 31 of the MOSFETs 30 and the cathode terminals 41 of the SBDs 40 are connected to the terminals 50u to 50w, respectively. In the semiconductor elements 300d to 300f, the source terminals 32 of the MOSFETs 30 and the anode terminals 42 of the SBDs 40 are connected to the wiring GND.

A gate terminal 33 of the MOSFET 30 is connected to, for example, a gate driver.

### <Problems Newly Found by Inventor>

FIG. 4 is a graph illustrating a conduction loss of each of the inverters INV1 to INV3 in the semiconductor devices 101 to 103 according to the first to third comparative examples. The horizontal axis represents a voltage V_{CE} between the collector terminal 11 and the emitter terminal 12 in the IGBT 10 or a voltage V_{DS} between the drain terminal 31 and the source terminal 32 in the MOSFET 30. The vertical axis represents a current I_{CE} between the collector terminal 11 and the emitter terminal 12 in the IGBT 10 or a current I_{DS} between the drain terminal 31 and the source terminal 32 in the MOSFET 30.

As illustrated in FIG. 4, the conduction loss of the IGBT 10 is represented by a magnitude indicated by y in the drawing. The IGBT 10 causes a conduction loss due to the voltage VCE that is constant even at a low load. This inevitably occurs from the structure of the IGBT 10. Specifically, a conduction loss LossIGBT of the IGBT 10 is expressed by the following formula (1). Regarding the conduction loss LossIGBT of the IGBT 10, a loss associated with the voltage VCE occurs even at a low load.

$$LossIGBT = {V}_{CE} \times {I}_{CE} \qquad ( 1 )$$

On the other hand, the conduction loss of the MOSFET 30 is represented by a magnitude indicated by x in the drawing. A conduction loss LossMOSFET of the MOSFET 30 is expressed by the following formula (2). The conduction loss LossMOSFET of the MOSFET 30 at a low load is smaller than the conduction loss LossIGBT of the IGBT 10. Here, Ron includes on-resistance.

$$LossMOSFET = {I}_{DS} \times {I}_{DS} \times Ron \qquad ( 2 )$$

FIG. 5 is a graph illustrating a tail current at the time of turn-off in the semiconductor device 101 according to the first comparative example, in which the horizontal axis represents time and the vertical axis represents the current I_{CE} or the voltage V_{CE}. In the case of the IGBT 10, a tail current occurs at the time of turn-off, as illustrated in FIG. 5. Therefore, the switching loss, when the IGBT 10 is turned off, is larger than that of the MOSFET 30. This inevitably occurs from the structure of the IGBT 10.

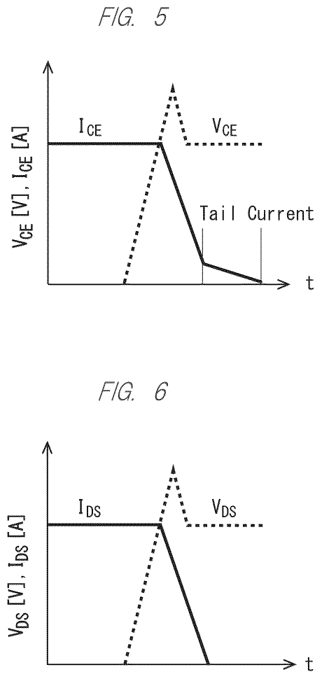

FIG. 6 is a graph illustrating a current at the time of turn-off in the semiconductor device 102 according to the second comparative example, in which the horizontal axis represents time and the vertical axis represents the current I_{DS} or the voltage V_{DS}. In the case of the MOSFET 30, no tail current occurs, or if it does, it is minimal, as illustrated in FIG. 6. Therefore, the switching loss, when the MOSFET 30 is turned off, is smaller than that of the IGBT 10.

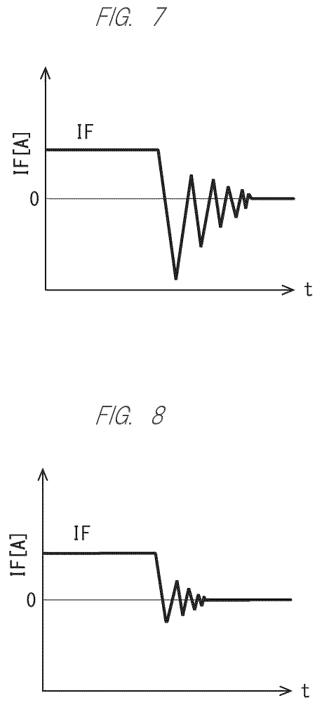

FIG. 7 is a graph illustrating a reverse recovery current of the FRD 20 in the semiconductor device 101 according to the first comparative example, in which the horizontal axis represents time and the vertical axis represents a current IF flowing through the FRD 20. For example, in the FRD 20 containing silicon (Si), the ringing of the reverse recovery current is large, and hence a switching loss is large, as illustrated in FIG. 7.

FIG. 8 is a graph illustrating a reverse recovery current of the SBD 40 in the semiconductor device 103 according to the third comparative example, in which the horizontal axis represents time and the vertical axis represents a current IF flowing through the SBD 40. As illustrated in FIG. 8, the ringing of the reverse recovery current is small in the SBD 40, and hence a switching loss is small.

From the characteristics of the IGBT 10 and the FRD 20 described above, the inverter INV1, including the IGBT 10 and the FRD 20 of the first comparative example, is characterized by low inverter efficiency in a vehicle actual load range (e.g., light load condition=30 kW, 50 N·m) such as a worldwide-harmonized light vehicles test cycle (WLTC) mode. As a result, the actual driving distance is shortened, and it is necessary to mount a large-capacity battery in order to ensure the driving distance in one charge.

On the other hand, the conduction losses of the inverters INV2 and INV3, using the MOSFETs 30 of the second and third comparative examples, are obtained from the formula (2) described above. Therefore, the conduction losses in low load ranges of the inverters INV2 and INV3 are small. Therefore, the inverters INV2 and INV3 can obtain high efficiency in the vehicle actual load range such as a WLTC mode. As a result, the actual driving distance is lengthened, and a long driving distance can be ensured with a smaller battery capacity.

On the other hand, in high load ranges, the conduction losses increase with the square of a load current. Therefore, in high load ranges, there is a feature that the efficiencies of the inverters INV2 and INV3 are decreased. In addition, the cost of a bare die containing SiC is high. Therefore, in the case where sufficient acceleration performance (150 KW, 400 N·m, etc.) is required as a traction motor output, if the traction motor is composed solely of the MOSFET 30 containing SiC, the cost becomes very high, resulting in poor cost performance. In driving in the WLTC mode, an output as high as 150 kW or the like is unnecessary. But, in order to improve drivability as a vehicle, sufficient acceleration performance is also required.

In order to realize carbon neutral, a traction motor system that realizes higher efficiency is required. When high efficiency is realized, it is possible to extend a driving distance in one charge and improve convenience of xEV, particularly, of EV (electric vehicle)/PHEV (plug-in hybrid electric vehicle). In addition, in order to increase the efficiencies of the inverters, the adoption of semiconductor elements made of low-loss IGBTs 10 and SiC is advancing. However, the inverter including the IGBT 10 has a large loss in a low load range and does not have high efficiency in the actual usage range of a vehicle, such as the WLTC mode or the like.

On the other hand, the inverter including the MOSFET 30 containing SiC has a feature that the loss in a low load range is small but the loss in a high load range is large. Therefore, a power module of hybrid system using both the IGBT 10 and the MOSFET 30 is highly expected. In the hybrid system, the inverter is driven by the MOSFET 30 at a low load and driven by the IGBT 10 at a high load, thereby eliminating both the disadvantages of the IGBT 10 and the MOSFET 30. In the hybrid system, the chip usage amount of the MOSFET 30 containing SiC can be reduced for the inverter/motor output assumed in a vehicle. Therefore, the hybrid system enables cost reduction.

The present disclosure proposes a method for reducing a switching loss by soft switching with a power module of hybrid system using the IGBT 10 and the MOSFET 30. Note that the soft switching is referred to as zero voltage switching (ZVS).

### First Embodiment

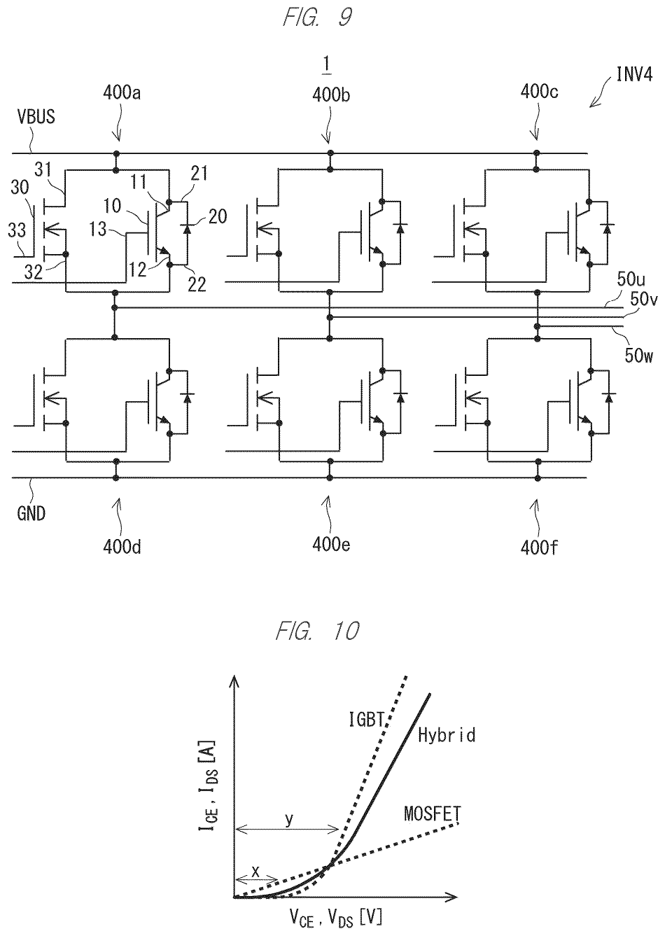

The present embodiment is an example of a hybrid system including both the IGBT 10 and the MOSFET 30 in an inverter. FIG. 9 is a circuit diagram illustrating an inverter INV4 in a semiconductor device 1 according to a first embodiment. As illustrated in FIG. 9, the semiconductor device 1 according to the first embodiment includes the inverter INV4. The inverter INV4 has the same function as that of the inverter INV1. The inverter INV4 includes a plurality of semiconductor elements 400a to 400f.

The semiconductor element 400a is disposed between wiring VBUS and a terminal 50u. The semiconductor element 400b is disposed between the wiring VBUS and a terminal 50v. The semiconductor element 400c is disposed between the wiring VBUS and a terminal 50w. On the other hand, the semiconductor element 400d is disposed between wiring GND and the terminal 50u. The semiconductor element 400e is disposed between the wiring GND and the terminal 50v. The semiconductor element 400f is disposed between the wiring GND and the terminal 50w.

The plurality of semiconductor elements 400a to 400f are collectively referred to as a semiconductor element 400. The semiconductor element 400 includes the IGBT 10, an FRD 20, and the MOSFET 30. In the semiconductor element 400, a collector terminal 11 of the IGBT 10 is connected to a cathode terminal 21 of the FRD 20 and a drain terminal 31 of the MOSFET 30. An emitter terminal 12 of the IGBT 10 is connected to an anode terminal 22 of the FRD 20 and a source terminal 32 of the MOSFET 30. As described above, the semiconductor element 400 connects the collector of the IGBT 10, the drain of the MOSFET 30, and the cathode of the diode, and connects the emitter of the IGBT 10, the source of the MOSFET 30, and the anode of the diode. The semiconductor element 400 is also simply referred to as an element.

In the semiconductor elements 400a to 400c, the collector terminals 11 of the IGBTs 10, the cathode terminals 21 of the FRDs 20, and the drain terminals 31 of the MOSFETs 30 are connected to the wiring VBUS. In the semiconductor elements 400a to 400c, the emitter terminals 12 of the IGBTs 10, the anode terminals 22 of the FRDs 20, and the source terminals 32 of the MOSFETs 30 are connected to the terminals 50u to 50w, respectively. In the semiconductor elements 400d to 400f, the collector terminals 11 of the IGBTs 10, the cathode terminals 21 of the FRDs 20, and the drain terminals 31 of the MOSFETs 30 are connected to the terminals 50u to 50w, respectively. In the semiconductor elements 400d to 400f, the emitter terminals 12 of the IGBTs 10, the anode terminals 22 of the FRDs 20, and the source terminals 32 of the MOSFETs 30 are connected to the wiring GND.

A gate terminal 13 of the IGBT 10 is connected to, for example, a gate driver. Similarly, a gate terminal 33 of the MOSFET 30 is connected to a gate driver. The semiconductor element 400 may include an FWD instead of the FRD 20.

FIG. 10 is a graph illustrating a conduction loss of the inverter INV4 in the semiconductor device 1 according to the first embodiment. The horizontal axis represents a voltage V_{CE} between the collector terminal 11 and the emitter terminal 12 in the IGBT 10 or a voltage V_{DS} between the drain terminal 31 and the source terminal 32 in the MOSFET 30. The vertical axis represents a current I_{CE} between the collector terminal 11 and the emitter terminal 12 in the IGBT 10 or a current I_{DS} between the drain terminal 31 and the source terminal 32 in the MOSFET 30. As illustrated in FIG. 10, the conduction loss of the inverter INV4 of hybrid system is smaller than that of the MOSFET 30 in a low load range and smaller than that of the IGBT 10 in a high load range.

As described above, in the semiconductor device 1 of the present embodiment, the inverter INV4 includes the IGBT 10 and the MOSFET 30 connected in parallel. The inverter INV4 causes a current to flow through the MOSFET 30 under a low load condition, and causes a current to flow through the IGBT 10 under a high load condition. As a result, the conduction loss of the inverter INV4 has intermediate characteristics among the inverter INV1 of the first comparative example, the inverter INV2 of the second comparative example, and the inverter INV3 of the third comparative example. Therefore, the inverter INV4 of the present embodiment can obtain high efficiency from the low load condition to the high load condition. In addition, the inverter INV4 of the present embodiment can reduce the usage amount of the MOSFET 30 containing high-cost SiC, thereby realizing cost reduction of the power module.

Next, a method for driving the inverter INV4 of hybrid system will be described. Examples of the method for driving the inverter INV4 of hybrid system include exclusive control, individual control, and simultaneous control. The outline of each control will be described below in (i) Outline of Exclusive Control, (ii) Outline of Individual Control, and (iii) Outline of Simultaneous Control.

### (i) Outline of Exclusive Control

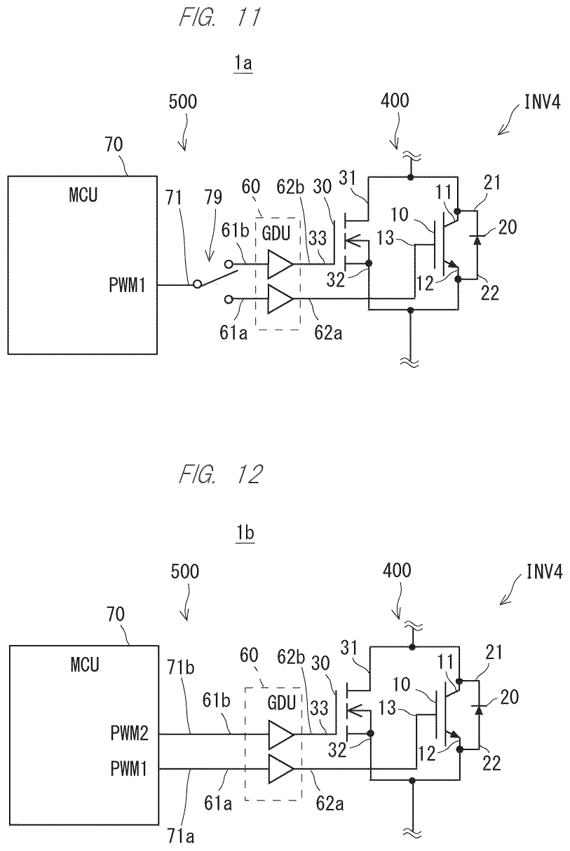

FIG. 11 is a circuit diagram illustrating the outline of exclusive control of an inverter INV4 in a semiconductor device 1a according to the first embodiment. As illustrated in FIG. 11, the semiconductor device 1a includes the inverter INV4 including a plurality of semiconductor elements 400 and a controller 500. Note that FIG. 11 illustrates one semiconductor element 400. In the present embodiment, the semiconductor device 1 that performs the exclusive control is collectively referred to as the semiconductor device 1a. The controller 500 includes a gate driver unit (GDU) 60 and a microcontroller unit (MCU) 70.

The GDU 60 functions as a gate driver and includes a terminal 61a, a terminal 61b, a terminal 62a, and a terminal 62b. The terminal 61a and the terminal 61b are connected to a terminal 71 of the MCU 70 via a switch 79. The terminal 62a is connected to the gate terminal 13 of the IGBT 10. The terminal 62b is connected to the gate terminal 33 of the MOSFET 30. A signal PWM1 input to the terminal 61a is output from the terminal 62a to the gate terminal 13 of the IGBT 10 through level shifting. The signal PWM1 input to the terminal 61b is output from the terminal 62b to the gate terminal 33 of the MOSFET 30 through level shifting. The signal PWM1 includes, for example, a pulse signal such as pulse width modulation (PWM).

The MCU 70 has one terminal 71. The MCU 70 includes a switch 79 that switches the terminal 71 to the terminal 61a or the terminal 61b. The MCU 70 outputs the signal PWM1 for turning on the gate of the IGBT 10 or the gate of the MOSFET 30 to the GDU 60 via the terminal 71. The MCU 70 outputs the signal PWM1 to the terminal 61a or the terminal 61b by switching the switch 79.

The MCU 70 outputs the signal PWM1 to the terminal 61a to turn on the gate of the IGBT 10. In addition, the MCU 70 outputs the signal PWM1 to the terminal 61b to turn on the gate of the MOSFET 30. In the exclusive control, one signal PWM1 is switched between the gate of the IGBT 10 and the gate of the MOSFET 30, as described above.

For the exclusive control, a single-channel drive circuit may be provided in the MCU 70. Then, the MCU 70 can exclusively control the IGBT 10 and the MOSFET 30 by switching the switch 79. In a low load range, the gate of the MOSFET 30 is turned on to drive the MOSFET 30. In a high load range, the gate of the IGBT 10 is turned on to drive the IGBT 10. However, this exclusive control method cannot simultaneously drive the IGBT 10 and the MOSFET 30. Therefore, the maximum output of the exclusive control does not become the sum of the respective outputs of the IGBT 10 and the MOSFET 30. Even when it is configured, for example, so that the output of the MOSFET 30 is 50 kW and the output of the IGBT 10 is 100 KW, the maximum output is 100 kW. Therefore, in order to configure to achieve an output of 150 KW, it is necessary to increase the number of the IGBTs 10 or the MOSFETs 30, resulting in an increase in cost.

### (ii) Outline of Individual Control

FIG. 12 is a circuit diagram illustrating the outline of individual control of an inverter INV4 in a semiconductor device 1b according to the first embodiment. As illustrated in FIG. 12, the semiconductor device 1b includes the inverter INV4 including a plurality of semiconductor elements 400 and a controller 500. In the present embodiment, the semiconductor device 1 that performs the individual control is collectively referred to as the semiconductor device 1b. In the case of individual control, the MCU 70 has two terminals 71a and 71b. The terminal 71a is connected to a terminal 61a, and the terminal 71b is connected to a terminal 61b.

The MCU 70 outputs a signal PWM1 for turning on or off the gate of the IGBT 10 to the GDU 60 via the terminal 71a and the terminal 61a. The MCU 70 outputs a signal PWM2 for turning on or off the gate of the MOSFET 30 to the GDU 60 via the terminal 71b and the terminal 61b. The MCU 70 outputs the signal PWM1 to the terminal 61a to turn on or off the gate of the IGBT 10. In addition, the MCU 70 outputs the signal PWM2 to the terminal 61b to turn on or off the gate of the MOSFET 30. In the individual control, the individual signals PWM1 and PWM2 are switched between the IGBT 10 and the MOSFET 30, as described above. The signal PWM2 includes, for example, a pulse signal such as pulse width modulation (PWM).

For the individual control, a two-channel drive circuit may be provided in the MCU 70. As a result, the MCU 70 can individually control the IGBT 10 and the MOSFET 30 by appropriately outputting the signal PWM1 and the signal PWM2. In a low load range, the gate of the MOSFET 30 is turned on to drive the MOSFET 30. In a high load range, the gate of the IGBT 10 is turned on to drive the IGBT 10. In the high load range, the MOSFET 30 can be driven by turning on the gate of the MOSFET 30, in addition to the IGBT 10. Therefore, the maximum output of the individual control becomes the sum of the respective outputs of the IGBT 10 and the MOSFET 30. When it is configured, for example, so that the output of the MOSFET 30 is 50 kW and the output of the IGBT 10 is 50 kW, the maximum output is 100 KW. As a disadvantage, the control by the MCU 70 becomes complicated, and a high-performance microcontroller is required as the MCU 70.

(iii) Outline of Simultaneous Control

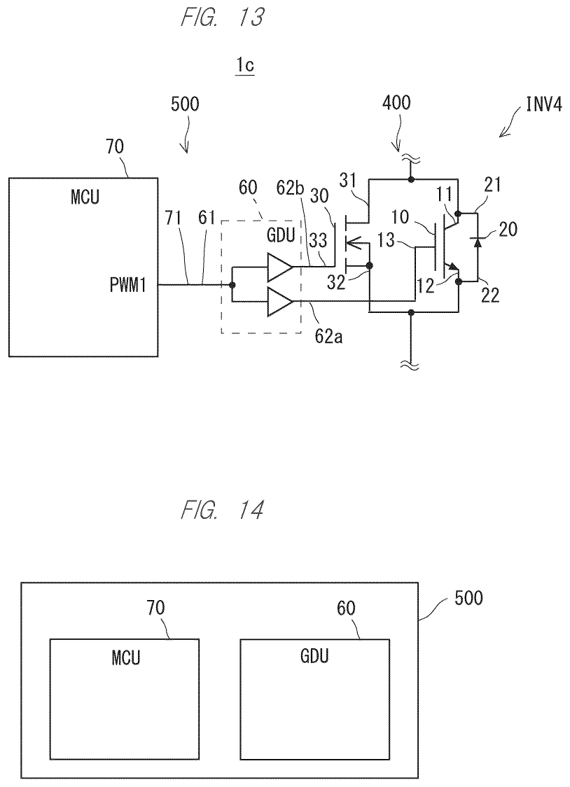

FIG. 13 is a circuit diagram illustrating the outline of simultaneous control of an inverter INV4 in a semiconductor device 1c according to the first embodiment. As illustrated in FIG. 13, the semiconductor device 1c includes an inverter INV4 including a plurality of semiconductor elements 400 and a controller 500. In the present embodiment, the semiconductor device 1 that performs the simultaneous control is collectively referred to as the semiconductor device 1c. In the case of the simultaneous control, a GDU 60 has a terminal 61, a terminal 62a, and a terminal 62b. The terminal 61 is connected to the terminal 71 of the MCU 70. The terminal 62a is connected to the gate terminal 13 of the IGBT 10. The terminal 62b is connected to the gate terminal 33 of the MOSFET 30. The signal PWM1 input to the terminal 61 branches inside the GDU 60. One branched signal PWM1 is output from the terminal 62a to the gate terminal 13 of the IGBT 10 through level shifting. The other branched signal PWM1 is output from the terminal 62b to the gate terminal 33 of the MOSFET 30 through level shifting.

The MCU 70 has one terminal 71. The terminal 71 is connected to the terminal 61. The MCU 70 outputs a signal PWM1 for turning on or off the gate of the IGBT 10 to the GDU 60 via the terminal 71 and the terminal 61, and outputs a signal PWM1 for turning on or off the gate of the MOSFET 30 to the GDU 60 via the terminal 71 and the terminal 61. The MCU 70 outputs the signal PWM1 to the terminal 61 to turn on or off the gate of the IGBT 10, and outputs the signal PWM1 to the terminal 61 to turn on or off the gate of the MOSFET 30. As described above, the simultaneous control simultaneously turns on or off the IGBT 10 and the MOSFET 30 with the same signal PWM1.

For the simultaneous control, a single-channel drive circuit may be provided in the MCU 70. As a result, the MCU 70 can simultaneously turn on or off the IGBT 10 and the MOSFET 30 by outputting the signal PWM1. In a low load range and in a range where the voltage drop of the component of the voltage V_{DS} of the MOSFET 30 is smaller than that of the component of the voltage V_{CE} of the IGBT 10, a current dominantly flows to the MOSFET 30 side. On the other hand, in a high load range, when the voltage drop of the component of the voltage V_{DS} on the MOSFET 30 side exceeds that of the component of the voltage V_{CE} of the IGBT 10, a current automatically dominantly flows to the IGBT 10 side. Since it is possible to simultaneously control the MOSFET 30 and the IGBT 10, the maximum output of the simultaneous control is an added value of the respective outputs of the IGBT 10 and the MOSFET 30. When it is configured, for example, so that the output of the MOSFET 30 is 50 kW and the output of the IGBT 10 is 50 kW, the maximum output is 100 kW. As a disadvantage, it is necessary to adjust turn-on and turn-off timings by an external circuit of the GDU 60 or the like. In addition, the output of the signal PWM1 from the MCU 70 is common between the IGBT 10 and the MOSFET 30, and hence on the IGBT 10 side, a switching loss, when the IGBT 10 is driven at a high carrier frequency (e.g., 20 kHz) that is a characteristic of SiC, may increase.

FIG. 14 is a block diagram illustrating a controller 500 in the semiconductor device 1 according to the first embodiment. As illustrated in FIG. 14, the controller 500 includes an MCU 70 and a GDU 60. The controller 500 controls the gate of the IGBT 10 and the gate of the MOSFET 30. The controller 500 outputs a first ON signal for turning on the gate of the IGBT 10 in the semiconductor element 400 and outputs a second ON signal for turning on the gate of the MOSFET 30. In addition, the controller 500 outputs a first OFF signal for turning off the gate of the IGBT 10 in the semiconductor element 400 and outputs a second OFF signal for turning off the gate of the MOSFET 30. In the present embodiment, the gate of the IGBT 10 may be referred to as a first gate, and the gate of the MOSFET 30 may be referred to as a second gate.

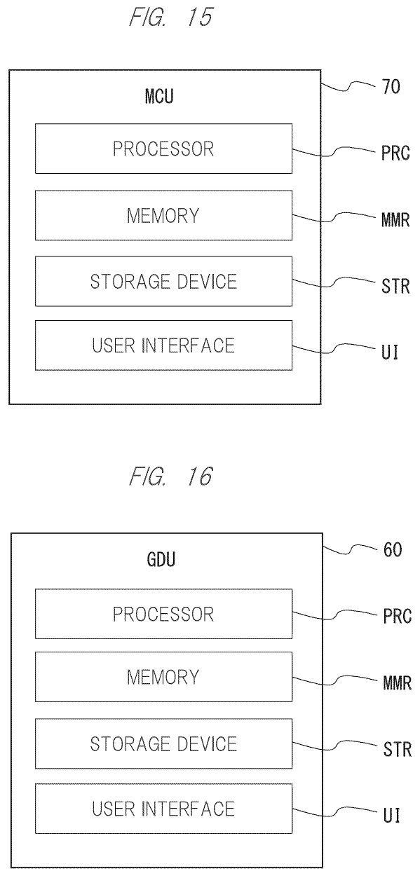

FIG. 15 is a block diagram illustrating the MCU 70 in the semiconductor device 1 according to the first embodiment. FIG. 16 is a block diagram illustrating the GDU 60 in the semiconductor device 1 according to the first embodiment. As illustrated in FIGS. 15 and 16, at least one of the MCU 70 and the GDU 60 may be an information processing device such as a microcomputer. Such an information processing device may further include a processor PRC, a memory MMR, a storage device STR, and a user interface UI. The storage device STR stores processing to be executed by each configuration of the information processing device as a program. In addition, the processor PRC allows a program to be read from the storage device STR into the memory MMR, whereby the program is executed. As a result, the processor PRC implements the function of each configuration in the information processing device. The user interface UI may include an input device such as a keyboard or a mouse, and an output device such as a display, a printer, or a speaker.

Each configuration included in the information processing device may be implemented with dedicated hardware. In addition, a part or all of each component may be implemented by a general-purpose or dedicated circuitry, a processor PRC, or the like, or a combination thereof. These may be configured by a single chip or may be configured by a plurality of chips connected via buses. A part or all of each component may be implemented by a combination of the above-described circuitry or the like and a program. As the processor PRC, a central processing unit (CPU), a graphics processing unit (GPU), a field-programmable gate array (FPGA), a quantum processor (quantum computer control chip), or the like can be used.

In addition, in a case where a part or all of each component of the information processing device is implemented by a plurality of information processing devices, circuits, and the like, the plurality of information processing devices, circuits, and the like may be arranged in a centralized manner or in a distributed manner.

Hereinafter, the turn-on and turn-off timings of the IGBT 10 and the MOSFET 30 are adjusted using the individual control and the simultaneous control in the semiconductor device 1 including the inverter INV4 of hybrid system. As a result, ZVS is performed at the turn-on and turn-off of the IGBT 10 when the switching loss is relatively large. That is, the controller 500 controls the gate of the IGBT 10 in a state where the gate of the MOSFET 30 is turned on.

Operations of the controller 500 will be described in the following (I) At Turn-On and (II) At Turn-Off.

### (I) At Turn-On

In controlling using the individual control and the simultaneous control, the controller 500 first turns on the MOSFET 30, and turns on the IGBT 10 after the voltage V_{DS} of the MOSFET 30 (and the voltage V_{CE} of the IGBT 10) decreases. Specifically, when turning on the gate (first gate) of the IGBT 10 and the gate (second gate) of the MOSFET 30, the controller 500 turns on the second gate by outputting the second ON signal, and turns on the first gate by outputting the first ON signal after the voltage V_{DC} between the drain and the source decreases. The controller 500 turns on the first gate by outputting the first ON signal after the voltage V_{DC} becomes, for example, 0.

By performing ZVS as described above, the switching loss is reduced. Note that the controller 500 may turn on the first gate by outputting the first ON signal after the voltage V_{CE} between the collector and the emitter decreases. In addition, the controller 500 may turn on the first gate by outputting the first ON signal after the voltage V_{CE} becomes 0.

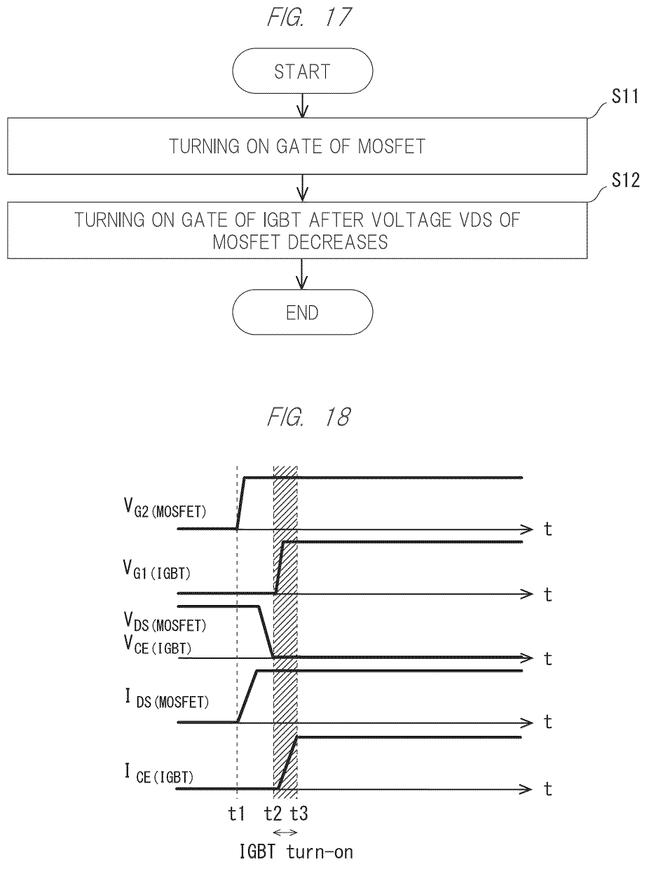

FIG. 17 is a flowchart illustrating a control method by the controller 500 in the semiconductor device 1 according to the first embodiment. As illustrated in FIG. 17, the method for controlling the semiconductor device 1 includes, when the gate (first gate) of the IGBT 10 and the gate (second gate) of the MOSFET 30 are turned on, step S11 of turning on the second gate, and step S12 of turning on the first gate after the voltage V_{DS} of the MOSFET 30 decreases.

FIG. 18 is a graph illustrating changes in a gate voltage V_{G1}, the voltage V_{CE}, and the current I_{CE} of the IGBT 10, and a gate voltage V_{G2}, the voltage V_{DS}, and the current I_{DS} of the MOSFET 30 in the semiconductor device 1 according to the first embodiment, in which the horizontal axis represents time, and the vertical axis represents each voltage and each current. As illustrated in FIG. 18, when the gate of the MOSFET 30 and the gate of the IGBT 10 are turned on, the controller 500 first turns on the gate of the MOSFET 30 by outputting the second ON signal for turning on the gate of the MOSFET 30 at a time t1. Then, the current I_{DS} flowing through the MOSFET 30 increases. As a result, the voltage V_{DS} of the MOSFET 30 decreases. The voltage V_{CE} of the IGBT 10 also decreases. By outputting the first ON signal for turning on the gate of the IGBT 10 at a time t2 when the voltage V_{DS} of the MOSFET 30 becomes, for example, 0 V, the controller 500 turns on the gate of the IGBT 10. Then, the current I_{CE} flowing through the IGBT 10 increases. At a time t3, the predetermined current I_{CE} flows through the IGBT 10.

Since the turn-on of the IGBT 10 is performed in a state where the voltage V_{DS} (and the voltage V_{CE}) decreases (e.g., 0 V), the switching loss of the IGBT 10 can be suppressed.

### (II) At Turn-Off

The controller 500 performs ZVS by first turning off the IGBT 10. Specifically, when the gate (first gate) of the IGBT 10 and the gate (second gate) of the MOSFET 30 are turned off, the controller 500 outputs the first OFF signal to turn off the first gate, and then outputs the second OFF signal to turn off the second gate. As a result, the semiconductor device 1 can improve the switching loss of the IGBT 10 and improve the efficiency of the inverter. In particular, in the simultaneous control, the switching loss on the IGBT 10 side can be suppressed even when the carrier frequency is set to be high for driving the MOSFET 30 containing SiC.

At the time of turn-off, the gate of the IGBT 10 is first turned off in a state where the gate of the MOSFET 30 is turned on. Since the gate of the MOSFET 30 is in an ON state, the gate of the IGBT 10 can be turned off in a state where the voltage V_{DS} (and the voltage VCE) decreases. Thus, ZVS can be performed. The IGBT 10 originally has a tail current, but it can be turned off in a state where the voltage V_{CE} is low, so that the switching loss can be suppressed.

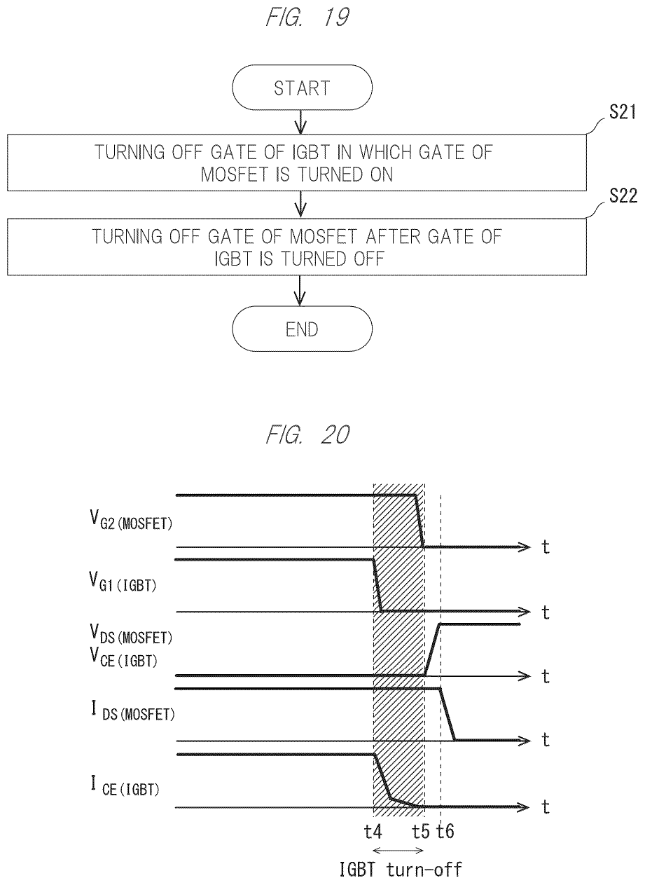

FIG. 19 is a flowchart illustrating a control method by the controller 500 in the semiconductor device 1 according to the first embodiment. As illustrated in FIG. 19, the method for controlling the semiconductor device 1 includes a step S21 of turning off the gate of the IGBT 10 in a state where the gate of the MOSFET 30 is turned on, and a step S22 of turning off the gate of the MOSFET 30 after the gate of the IGBT 10 is turned off.

FIG. 20 is a graph illustrating changes in the gate voltage V_{G1}, the voltage V_{CE}, and the current I_{CE} of the IGBT 10, and the gate voltage V_{G2}, the voltage V_{DS}, and the current I_{DS} of the MOSFET 30 in the semiconductor device 1 according to the first embodiment, in which the horizontal axis represents time, and the vertical axis represents each voltage and each current. When the gate of the MOSFET 30 and the gate of the IGBT 10 are turned off, the controller 500 outputs the first OFF signal for turning off the gate of the IGBT 10 at a time t4 in a state where the gate of the MOSFET 30 is turned on, as illustrated in FIG. 20. As a result, the controller 500 first turns off the gate of the IGBT 10. Thereafter, the current I_{CE} flowing through the IGBT 10 decreases. The controller 500 outputs the second OFF signal for turning off the gate of the MOSFET 30 after the gate of the IGBT 10 is turned off. As a result, the gate of the MOSFET 30 is turned off.

Since the turn-off of the IGBT 10 is performed in a state where the voltage V_{CE} is lower than a predetermined value (e.g., 0 V), the switching loss, due to the tail current of the IGBT 10, can be suppressed by ZVS.

n<Semiconductor Device Performing Individual Control> and <Semiconductor Device Performing Simultaneous Control> below, examples of the respective semiconductor device 1b and semiconductor device 1c will be described.

### <Semiconductor Device Performing Individual Control>

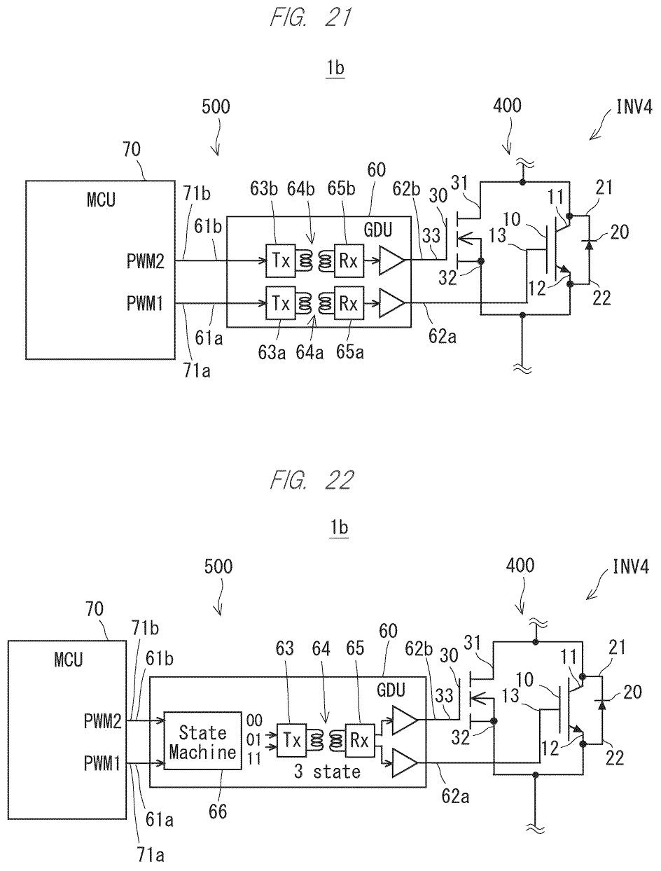

FIG. 21 is a circuit diagram illustrating a GDU 60 and an MCU 70 that perform individual control in the semiconductor device 1b according to the first embodiment. As illustrated in FIG. 21, the controller 500 includes the GDU 60 and the MCU 70. The GDU 60 outputs the first ON signal to the gate of the IGBT 10. In addition, the GDU 60 outputs the second ON signal to the gate of the MOSFET 30. The GDU 60 outputs the first OFF signal to the gate of the IGBT 10. In addition, the GDU 60 outputs the second OFF signal to the gate of the MOSFET 30.

The MCU 70 outputs a signal PWM1 for causing the GDU 60 to output the first ON signal to the GDU 60. In addition, the MCU 70 outputs a signal PWM2 for causing the GDU 60 to output the second ON signal to the GDU 60. The MCU 70 outputs a signal PWM1 for causing the GDU 60 to output the first OFF signal to the GDU 60. In addition, the MCU 70 outputs a signal PWM2 for causing the GDU 60 to output the second OFF signal to the GDU 60.

The signal PWM1 for causing the GDU 60 to output the first ON signal may be referred to as a first pulse signal, and the signal PWM2 for causing the GDU 60 to output the second ON signal may be referred to as a second pulse signal. The signal PWM1 for causing the GDU 60 to output the first OFF signal may be referred to as a third pulse signal, and the signal PWM2 for causing the GDU 60 to output the second OFF signal may be referred to as a fourth pulse signal.

When the gate of the IGBT 10 and the gate of the MOSFET 30 are individually controlled, the MCU 70 outputs a second pulse signal P to the GDU 60, causing the GDU 60 to output the second ON signal. As a result, the gate of the MOSFET 30 is turned on. Then, the controller 500 outputs the first pulse signal to the GDU 60 after the voltage V_{DS} of the MOSFET 30 decreases, causing the GDU 60 to output the first ON signal. As a result, the gate of the IGBT 10 is turned on. In addition, the MCU 70 outputs a third pulse signal P to the GDU 60 to cause the GDU 60 to output the first OFF signal. As a result, the gate of the IGBT 10 is turned off. The controller 500 outputs the fourth pulse signal to the GDU 60 after the gate of the IGBT 10 is turned off, causing the GDU 60 to output the second OFF signal. As a result, the gate of the MOSFET 30 is turned off.

The GDU 60 includes a transmitter 63a, a transmitter 63b, an isolator 64a, an isolator 64b, a receiver 65a, and a receiver 65b in addition to the terminal 61a, the terminal 61b, the terminal 62a, and the terminal 62b. In the case of the individual control, the GDU 60 individually includes two-channel isolators 64a and 64b to drive the IGBT 10 and drive the MOSFET 30. In the case of the individual control, the MCU 70 outputs the signal PWM1 and the signal PWM2 to adjust the ON timings and OFF timings of the IGBT 10 and the MOSFET 30.

The transmitter 63a is connected to the terminal 61a. The receiver 65a is connected to a level shifter connected to the terminal 62a. The isolator 64a is disposed between the transmitter 63a and the receiver 65a, in which a signal is indirectly transmitted without the transmitter 63a and the receiver 65a directly connected. For example, the isolator 64a includes a primary inductor and a secondary inductor. The transmitter 63a transmits the signal PWM1 (first pulse signal) output from the MCU 70 to the isolator 64a. Following the reception of the signal PWM1 (first pulse signal) by the isolator 64a, the receiver 65a outputs the first ON signal to the gate of the IGBT 10. In addition, the transmitter 63a transmits the signal PWM1 (third pulse signal) output from the MCU 70 to the isolator 64a. Following the reception of the signal PWM1 (third pulse signal) by the isolator 64a, the receiver 65a outputs the first OFF signal to the gate of the IGBT 10.

The transmitter 63b is connected to the terminal 61b. The receiver 65b is connected to a level shifter connected to the terminal 62b. The isolator 64b is disposed between the transmitter 63b and the receiver 65b, in which a signal is indirectly transmitted without the transmitter 63b and the receiver 65b directly connected. The transmitter 63b transmits the signal PWM2 (second pulse signal) output from the MCU 70 to the isolator 64b. Following the reception of the signal PWM2 (second pulse signal) by the isolator 64b, the receiver 65b outputs the second ON signal to the gate of the MOSFET 30. In addition, the transmitter 63b transmits the signal PWM2 (fourth pulse signal) output from the MCU 70 to the isolator 64b. Following the reception of the signal PWM2 (fourth pulse signal) by the isolator 64b, the receiver 65b outputs the second OFF signal to the gate of the MOSFET 30.

Since the semiconductor device 1b can individually control the IGBT 10 and the MOSFET 30, signals for turning on and off the gates of the IGBT 10 and the MOSFET 30 can be output at any timings from the MCU 70. In the case of the individual control, the MCU 70 adjusts the ON timings and OFF timings of the IGBT 10 and the MOSFET 30, as described above.

FIG. 22 is a circuit diagram illustrating a GDU 60 and an MCU 70 that perform individual control in a semiconductor device 1b according a modification of the first embodiment. As illustrated in FIG. 22, the GDU 60 of the modification includes a transmitter 63, an isolator 64, a receiver 65, and a state machine 66 in addition to the terminal 61a, the terminal 61b, the terminal 62a, and the terminal 62b. The MCU 70 includes a terminal 71a and a terminal 71b.

The terminals 71a and 71b of the MCU 70 are connected to the state machine 66 via the terminals 61a and 61b of the GDU 60, respectively. The state machine 66 is connected to the transmitter 63. The receiver 65 is connected to a level shifter connected to the terminal 62a and a level shifter connected to the terminal 62b. The isolator 64 is disposed between the transmitter 63 and the receiver 65, in which a signal is indirectly transmitted without the transmitter 63 and the receiver 65 directly connected.

Based on the signals PWM1 and PWM2 received from the MCU 70, the state machine 66 transmits state signals indicating the following three states to the transmitter 63 in 2 bits. The transmitter 63 outputs the state signals to the isolator 64. Based on the state signals received by the isolator 64, the receiver 65 outputs signals to the terminals 62a and 62b.
00 (third state): gate-off of IGBT 10, gate-off of MOSFET 30
01 (second state): gate-off of IGBT 10, gate-on of MOSFET 30
11 (first state): gate-on of IGBT 10, gate-on of MOSFET 30

Based on the signals PWM1 (first pulse signal and third pulse signal) and the signals PWM2 (second pulse signal and fourth pulse signal), the state machine 66 outputs a first state signal for outputting the first ON signal and the second ON signal, a second state signal for outputting the first OFF signal and the second ON signal, and a third state signal for outputting the first OFF signal and the second OFF signal.

The transmitter 63 transmits the first state signal, the second state signal, and the third state signal output from the state machine 66 to the isolator 64. Following the reception of the first state signal, the second state signal, and the third state signal by the isolator 64, the receiver 65 outputs the first ON signal, the first OFF signal, the second ON signal, and the second OFF signal.

For example, when the first state signal is output after the second state signal is output from the state machine 66, the receiver 65 outputs the second ON signal following the reception of the second state signal and the first state signal by the isolator 64, and outputs the first ON signal after the voltage V_{DS} of the MOSFET 30 decreases. In addition, for example, when the third state signal is output after the second state signal is output from the state machine 66, the receiver 65 outputs the first OFF signal following the reception of the second state signal and the third state signal by the isolator 64, and then outputs the second OFF signal.

### <Semiconductor Device Performing Simultaneous Control>

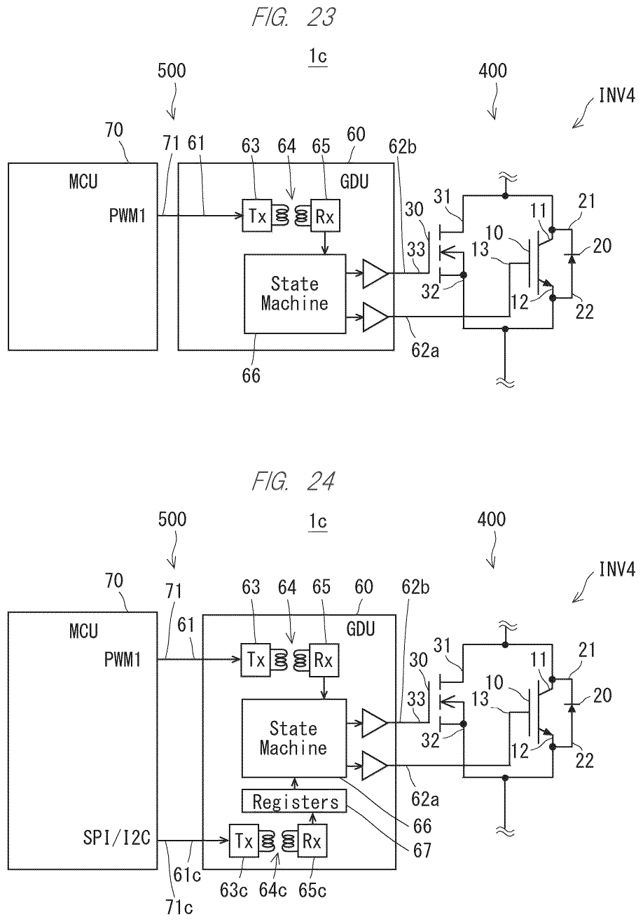

FIG. 23 is a circuit diagram illustrating a GDU 60 and an MCU 70 that perform simultaneous control in the semiconductor device 1c according to the first embodiment. As illustrated in FIG. 23, the GDU 60 includes a transmitter 63, an isolator 64, a receiver 65, and a state machine 66 in addition to the terminal 61, the terminal 62a, and the terminal 62b. When the simultaneous control is performed, the MCU 70 outputs a signal PWM1 (which may be referred to as a fifth pulse signal) for outputting at least one of a first ON signal for turning on the gate of the IGBT 10 and a second ON signal for turning on the gate of the MOSFET 30 to the GDU 60. In addition, the MCU 70 outputs a signal PWM1 (which may be referred to as a sixth pulse signal) for outputting at least one of a first OFF signal for turning off the gate of the IGBT 10 and a second OFF signal for turning off the gate of the MOSFET 30 to the GDU 60.

When the gate of the IGBT 10 and the gate of the MOSFET 30 are simultaneously controlled, the MCU 70 outputs the fifth pulse signal to the GDU to drive the GDU 60. As a result, the GDU 60 outputs the second ON signal, and outputs the first ON signal after the voltage V_{DS} of the MOSFET 30 decreases. In addition, the MCU 70 outputs the sixth pulse signal to the GDU to drive the GDU 60. As a result, the GDU60 outputs the first OFF signal, and then outputs the second OFF signal.

The transmitter 63 is connected to the terminal 61, and the receiver 65 is connected to the state machine 66. The isolator 64 is disposed between the transmitter 63 and the receiver 65. The transmitter 63 transmits the fifth pulse signal output from the MCU 70 to the isolator 64. Following the reception of the fifth pulse signal by the isolator 64, the receiver 65 outputs a first control signal to the state machine 66. The first control signal is a signal that causes the state machine 66 to output the second ON signal, and to output the first ON signal after the voltage V_{DS} of the MOSFET 30 decreases. Therefore, the state machine 66 outputs the second ON signal when receiving the first control signal from the receiver 65, and outputs the first ON signal after the voltage V_{DS} of the MOSFET 30 decreases. As a result, the controller 500 turns on the gate of the MOSFET 30, and turns on the gate of the IGBT 10 after the voltage V_{DS} decreases.

The transmitter 63 transmits the sixth pulse signal output from the MCU 70 to the isolator 64. Following the reception of the sixth pulse signal by the isolator 64, the receiver 65 outputs a second control signal to the state machine 66. The second control signal is a signal that causes the state machine 66 to output the first OFF signal and then output the second OFF signal. Therefore, the state machine 66 outputs the first OFF signal when receiving the second control signal from the receiver 65, and then outputs the second OFF signal. As a result, the controller 500 turns off the gate of the IGBT 10, and then turns off the gate of the MOSFET 30. In the case of the simultaneous control, the GDU 60 adjusts the ON timings and OFF timings of the IGBT 10 and the MOSFET 30, as described above.

FIG. 24 is a circuit diagram illustrating a GDU 60 and an MCU 70 that perform simultaneous control in a semiconductor device 1c according to a first modification of the first embodiment. As illustrated in FIG. 24, the GDU 60 of the first modification includes a transmitter 63, an isolator 64, a receiver 65, a state machine 66, a register 67, a terminal 61c, a transmitter 63c, an isolator 64c, and a receiver 65c in addition to the terminal 61, the terminal 62a, and the terminal 62b.

The MCU 70 includes a terminal 71c in addition to the terminal 71. The MCU 70 outputs a signal (which may be referred to as a seventh pulse signal) for setting the timings when the gates of the IGBT 10 and the MOSFET 30 are turned on, to the serial terminal 71c such as a serial peripheral interface (SPI) or an inter-integrated circuit (I2C). In addition, the MCU 70 outputs a signal (which may be referred to as an eighth pulse signal) for setting the timings when the gates of the IGBT 10 and the MOSFET 30 are turned off, to the terminal 71c. The terminal 71c is connected to the terminal 61c.

The configurations of the transmitter 63, the isolator 64, the receiver 65, and the state machine 66 are similar to those of the semiconductor device 1c described above. However, the state machine 66 of the first modification adjusts, following the reception of the first control signal, the timings when the first ON signal and the second ON signal are output, by the register 67. The state machine 66 of the first modification also adjusts, following the reception of the second control signal, the timings when the first OFF signal and the second OFF signal are output, by the register 67.

The transmitter 63c is connected to the terminal 61c, and the receiver 65c is connected to the register 67. The isolator 64c is disposed between the transmitter 63c and the receiver 65c. In the modification, the isolator 64c that sets the turn-on and the turn-off is included separately from the single-channel isolator 64 that controls the gates of the IGBT 10 and the MOSFET 30, as described above.

The transmitter 63c transmits the seventh pulse signal output from the MCU 70 to the isolator 64c. Following the reception of the seventh pulse signal by the isolator 64c, the receiver 65c outputs a first adjustment signal. The first adjustment signal is a signal for causing the register 67 to adjust, following the reception of the first control signal by the state machine 66, the timings when the first ON signal and the second ON signal are output. Therefore, the register 67 adjusts the timings when the state machine 66 outputs the second ON signal following the reception of the first adjustment signal, and when the state machine 66 outputs the first ON signal after the voltage V_{DS} of the MOSFET 30 decreases.

In addition, the transmitter 63c transmits the eighth pulse signal output from the MCU 70 to the isolator 64c. Following the reception of the eighth pulse signal by the isolator 64c, the receiver 65c outputs a second adjustment signal. The second adjustment signal is a signal for causing the register 67 to adjust, following the reception of the second control signal by the state machine 66, the timings when the first OFF signal and the second OFF signal are output. Therefore, the register 67 adjusts the timing when the second OFF signal is output after the state machine 66 outputs the first OFF signal following the reception of the second adjustment signal.

The register 67 may store, in advance, the timings when the gate of the IGBT 10 and the gate of the MOSFET 30 are turned on and off. Following the reception of the first adjustment signal and the second adjustment signal from the receiver 65c, the register 67 outputs, to the state machine 66, the timings when the gate of the IGBT 10 and the gate of the MOSFET 30 are turned on and off, based on the stored timings. The state machine 66 outputs the first ON signal, the second ON signal, and the like to the terminal 62a and the terminal 62b on the basis of the timings input from the register 67. In the case of the simultaneous control, the GDU 60 adjusts the ON timings and OFF timings of the IGBT 10 and the MOSFET 30, as described above.

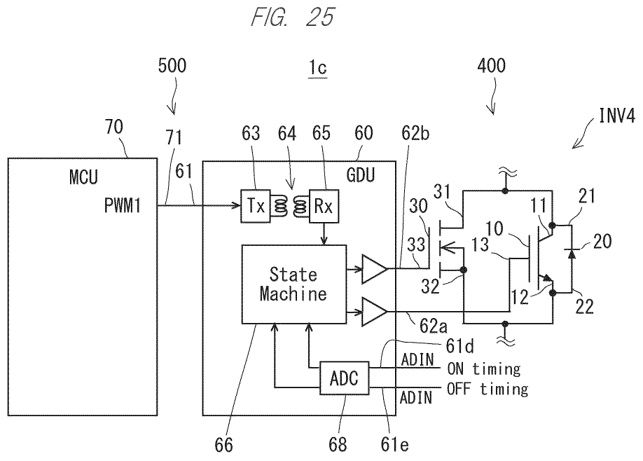

FIG. 25 is a circuit diagram illustrating a GDU 60 and an MCU 70 that perform simultaneous control in a semiconductor device 1c according to a second modification of the first embodiment. As illustrated in FIG. 25, the GDU 60 includes a transmitter 63, an isolator 64, a receiver 65, a state machine 66, an analog-to-digital converter (ADC) 68, a terminal 61d, and a terminal 61e in addition to the terminal 61, the terminal 62a, and the terminal 62b. In the present modification, the timings when the first ON signal, the second ON signal, and the like are output are adjusted from voltage values input from the outside, instead of the register 67 of the first modification described above. That is, in the second modification, a secondary-side setting pin 2 input using the terminal 61d and the terminal 61e for turning on and turning off is configured separately from the single-channel isolator 64 that controls the gates of the IGBT 10 and the MOSFET 30. As a result, the timings for turning on and turning off are controlled.

A first voltage value is input from the outside to the terminal 61d. The first voltage value adjusts the timings when the state machine 66 outputs the second ON signal, and when the state machine 66 outputs the first ON signal. A second voltage value is input from the outside to the terminal 61e. The second voltage value adjusts the timings when the state machine 66 outputs the first OFF signal, and when the state machine 66 outputs the second OFF signal.

The configurations of the transmitter 63, the isolator 64, the receiver 65, and the state machine 66 are similar to those of the semiconductor device 1c described above. However, the state machine 66 of the second modification adjusts, following the reception of the first control signal, the timings when the first ON signal and the second ON signal are output, on the basis of the voltage values input from the outside. Specifically, the ADC 68 outputs a first digital value for adjusting the timings when the state machine 66 outputs the second ON signal following the reception of the first voltage value from the outside, and when the state machine 66 outputs the first ON signal after the voltage V_{DS} of the MOSFET 30 decreases. In addition, the ADC 68 outputs, to the state machine 66, a second digital value for adjusting the timings when the state machine 66 outputs the first OFF signal following the reception of the second voltage value from the outside, and when the state machine 66 outputs the second OFF signal.

In the case of the simultaneous control, the GDU 60 adjusts the ON timings and OFF timings of the IGBT 10 and the MOSFET 30, as described above.

Next, effects of the present embodiment will be described. The semiconductor device 1 of the present embodiment controls the gate of the IGBT 10 in a state where the gate of the MOSFET 30 in the inverter INV4 is turned on. This reduces a switching loss. Therefore, the power loss of the semiconductor device 1 including the inverter INV4 can be reduced, and the efficiency of the inverter INV4 can be improved. For example, in controlling using the individual control and the simultaneous control, the controller 500 first turns on the MOSFET 30, and turns on the IGBT 10 after the voltage V_{DS} of the MOSFET 30 decreases. In addition, the controller 500 turns on the MOSFET 30 after turning off the IGBT 10. As a result, ZVS can be performed, and the switching loss can be further reduced.

In controlling using the individual control and the simultaneous control, the turn-on and turn-off timings can be regulated by using the state machine 66. In addition, by adjusting the timings by the state machine 66 with the register 67, the ADC 68, and the like, the regularity of the timings can be further improved.

The inverter INV4 includes the semiconductor element 400 including the IGBT 10 and the MOSFET 30. This makes it possible to obtain high efficiency from a low load condition to a high load condition. In addition, the inverter INV4 can reduce the usage amount of the MOSFET 30 containing high-cost SiC, thereby realizing cost reduction of the power module.

Although the disclosure made by the present inventor has been specifically described based on the embodiments, the present disclosure is not limited to the embodiments and the modifications, and it is needless to say that various modifications can be made without departing from the gist of the present disclosure. For example, appropriate combinations of the configurations of the first to third comparative examples, the first embodiment, and the respective modifications are also within the scope of the technical idea of the embodiments. In addition, the following configurations are also within the scope of the technical idea of the embodiments.

### (Appendix A1)

A semiconductor device including
a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET, in which
the controller controls the first gate in a state where the second gate is turned on.

### (Appendix A2)

The semiconductor device according to Appendix A1, in which
the controller:
outputs a first OFF signal for turning off the first gate and a second OFF signal for turning off the second gate; and
when turning off the first gate and the second gate,
controls such that the first gate is turned off by outputting the first OFF signal, and then
the second gate is turned off by outputting the second OFF signal.

### (Appendix A3)

The semiconductor device according to Appendix A2, in which the controller:
outputs a first ON signal for turning on the first gate and a second ON signal for turning on the second gate; and
when turning on the first gate and the second gate,
controls such that the second gate is turned on by outputting the second ON signal, and
the first gate is turned on by outputting the first ON signal after a voltage between the drain and the source decreases.

### (Appendix A4)

The semiconductor device according to Appendix A3, in which
the controller turns on the first gate by outputting the first ON signal after the voltage between the drain and the source decreases.

### (Appendix A5)

The semiconductor device according to Appendix A2,
the controller including
a GDU that outputs the first OFF signal to the first gate and outputs the second OFF signal to the second gate, and
an MCU that outputs a third pulse signal for causing the GDU to output the first OFF signal to the GDU and outputs a fourth pulse signal for causing the GDU to output the second OFF signal to the GDU, in which
when the first gate and the second gate are individually controlled,
the MCU
outputs the third pulse signal to the GDU, and then
outputs the fourth pulse signal to the GDU.

### (Appendix A6)

The semiconductor device according to Appendix A5, in which:
the GDU outputs a first ON signal for turning on the first gate to the first gate and outputs a second ON signal for turning on the second gate to the second gate; and
the MCU
outputs, to the GDU, a second pulse signal for causing the GDU to output the second ON signal, and
outputs, to the GDU, a first pulse signal for causing the GDU to output the first ON signal after the voltage between the drain and the source drops.

### (Appendix A7)

The semiconductor device according to Appendix A6, in which
the GDU includes:
a first transmitter that transmits the third pulse signal output from the MCU to a first isolator;
a first receiver that outputs the first OFF signal following the reception of the third pulse signal by the first isolator;
a second transmitter that transmits the fourth pulse signal output from the MCU to a second isolator; and
a second receiver that outputs the second OFF signal following the reception of the fourth pulse signal by the second isolator.

### (Appendix A8)

The semiconductor device according to Appendix A7, in which
the first transmitter transmits the first pulse signal output from the MCU to the first isolator,
the first receiver outputs the first ON signal following the reception of the first pulse signal by the first isolator,
the second transmitter transmits the second pulse signal output from the MCU to the second isolator, and
the second receiver outputs the second ON signal following the reception of the second pulse signal by the second isolator.

### (Appendix A9)

The semiconductor device according to Appendix A6, in which
the GDU includes:
a first state machine that, based on the first pulse signal, the second pulse signal, the third pulse signal, and the fourth pulse signal, outputs a second state signal for outputting the first OFF signal and the second ON signal and outputs a third state signal for outputting the first OFF signal and the second OFF signal;
a third transmitter that outputs the second state signal and the third state signal output from the first state machine to a third isolator; and
a third receiver that outputs the first OFF signal following the reception of the second state signal and the third state signal by the third isolator, and then outputs the second OFF signal.

### (Appendix A10)

The semiconductor device according to Appendix A9, in which
based on the first pulse signal, the second pulse signal, the third pulse signal, and the fourth pulse signal, the first state machine outputs a first state signal for outputting the first ON signal and the second ON signal,
the third transmitter transmits the first state signal and the second state signal output from the first state machine to the third isolator, and
the third receiver outputs the second ON signal following the reception of the first state signal and the second state signal by the third isolator, and outputs the first ON signal after the voltage between the drain and the source decreases.

### (Appendix A11)

The semiconductor device according to Appendix A2,
the controller including:
a GDU that outputs the first OFF signal to the first gate and outputs the second OFF signal to the second gate; and
an MCU that outputs, to the GDU, a sixth pulse signal for causing the GDU to output at least one of the first OFF signal and the second OFF signal, in which
when the first gate and the second gate are simultaneously controlled,
the MCU drives the GDU by outputting the sixth pulse signal to the GDU, and
the GDU outputs the second OFF signal after outputting the first OFF signal.

### (Appendix A12)

The semiconductor device according to Appendix A11, in which
the GDU outputs a first ON signal for turning on the first gate to the first gate and outputs a second ON signal for turning on the second gate to the second gate, and
the MCU
drives the GDU by outputting, to the GDU, a fifth pulse signal for causing the GDU to output at least one of the first ON signal and the second ON signal, and
the GDU outputs the second ON signal, and outputs the first ON signal after the voltage between the drain and the source decreases.

### (Appendix A13)

The semiconductor device according to Appendix A12, in which
the GDU includes
a fourth transmitter that transmits the sixth pulse signal output from the MCU to a fourth isolator,
a fourth receiver that outputs a second control signal following the reception of the sixth pulse signal by the fourth isolator, and
a second state machine that outputs the first OFF signal following the reception of the second control signal, and then outputs the second OFF signal.

### (Appendix A14)

The semiconductor device according to Appendix A13, in which
the fourth transmitter transmits the fifth pulse signal output from the MCU to the fourth isolator,
the fourth receiver outputs a first control signal following the reception of the fifth pulse signal by the fourth isolator, and
the second state machine outputs the second ON signal following the reception of the first control signal, and outputs the first ON signal after the voltage between the drain and the source decreases.

### (Appendix A15)

The semiconductor device according to Appendix A14, in which
the MCU outputs an eighth pulse signal, and
the GDU includes:
a fifth transmitter that transmits the eighth pulse signal output from the MCU to a fifth isolator;
a fifth receiver that outputs a second adjustment signal following the reception of the eighth pulse signal by the fifth isolator; and
a register that adjusts a timing when the second OFF signal is output after the second state machine outputs the first OFF signal following the reception of the second adjustment signal.

### (Appendix A16)

The semiconductor device according to Appendix A15, in which
the MCU outputs a seventh pulse signal,
the fifth transmitter transmits the seventh pulse signal output from the MCU to the fifth isolator,
the fifth receiver outputs a first adjustment signal following the reception of the seventh pulse signal by the fifth isolator, and
the register adjusts timings when the second state machine outputs the second ON signal following the reception of the first adjustment signal, and when the second state machine outputs the first ON signal after the voltage between the drain and the source decreases.

### (Appendix A17)

The semiconductor device according to Appendix A14, in which
the GDU includes an ADC that outputs a second digital value for adjusting timings when the second state machine outputs the first OFF signal following the reception of a second voltage value from the outside, and when it then outputs the second OFF signal.

### (Appendix A18)

The semiconductor device according to Appendix A17, in which
the ADC outputs a first digital value for adjusting timings when the second state machine outputs the second ON signal following the reception of a first voltage value from the outside, and when the second state machine outputs the first ON signal after the voltage between the drain and the source decreases.

### (Appendix B1)

A method for controlling a semiconductor device, the semiconductor device including a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET, the method including
a step of controlling the first gate in a state where the second gate is turned on.

### (Appendix B2)

The method for controlling a semiconductor device according to Appendix B1, in which
the step of controlling the first gate in a state where the second gate is turned on includes:
when the first gate and the second gate are turned on, a step of turning on the second gate by the controller outputting the second ON signal; and
a step of turning on the first gate by the controller outputting the first ON signal after a voltage between the drain and the source decreases.

### (Appendix B3)

The method for controlling a semiconductor device according to Appendix B2, in which
in the step of turning on the first gate,
the controller turns on the first gate by outputting the first ON signal
after the voltage between the drain and the source decreases.

### (Appendix B4)

The method for controlling a semiconductor device according to Appendix B2, in which
the step of controlling the first gate in a state where the second gate is turned on further includes:
when the first gate and the second gate are turned off, a step of the controller turning off the first gate by outputting a first OFF signal for turning off the first gate; and
a step of the controller turning off the second gate by outputting a second OFF signal for turning off the second gate after turning off the first gate.

### (Appendix B5)

The method for controlling a semiconductor device according to Appendix B2, the controller including:
a GDU that outputs the first ON signal to the first gate and outputs the second ON signal to the second gate; and
an MCU that outputs a first pulse signal for causing the GDU to output the first ON signal to the GDU and outputs a second pulse signal for causing the GDU to output the second ON signal to the GDU, in which
when the first gate and the second gate are individually controlled,
in the step of turning on the second gate,
the MCU causes the GDU to output the second ON signal by outputting the second pulse signal to the GDU, and
in the step of turning on the first gate,
the MCU causes the GDU to output the first ON signal by outputting the first pulse signal to the GDU after the voltage between the drain and the source decreases.

### (Appendix B6)

The method for controlling a semiconductor device according to Appendix B5, in which
the step of controlling the first gate in a state where the second gate is turned on further includes:
a step of the MCU causing the GDU to output a first OFF signal for turning off the first gate, by the MCU outputting, to the GDU, a third pulse signal for causing the GDU to output the first OFF signal in order to turn off the first gate; and
a step of the MCU causing the GDU to output a second OFF signal for turning off the second gate, by the MCU outputting, to the GDU and after the first gate is turned off, a fourth pulse signal for causing the GDU to output the second OFF signal in order to turn off the second gate.

### (Appendix B7)

The method for controlling a semiconductor device according to Appendix B6, in which
the GDU includes:
a first transmitter that transmits the first pulse signal output from the MCU to a first isolator;
a first receiver that outputs the first ON signal following the reception of the first pulse signal by the first isolator;
a second transmitter that transmits the second pulse signal output from the MCU to a second isolator; and
a second receiver that outputs the second ON signal following the reception of the second pulse signal by the second isolator.

### (Appendix B8)

The method for controlling a semiconductor device according to Appendix B7, in which
the first transmitter transmits the third pulse signal output from the MCU to the first isolator,
the first receiver outputs the first OFF signal following the reception of the third pulse signal by the first isolator,
the second transmitter transmits the fourth pulse signal output from the MCU to the second isolator, and
the second receiver outputs the second OFF signal following the reception of the fourth pulse signal by the second isolator.

### (Appendix B9)

The method for controlling a semiconductor device according to Appendix B6, in which
the GDU includes:
a first state machine that, based on the first pulse signal, the second pulse signal, the third pulse signal, and the fourth pulse signal, outputs a first state signal for outputting the first ON signal and the second ON signal and outputs a second state signal for outputting the first OFF signal and the second ON signal;
a third transmitter that transmits the first state signal and the second state signal output from the first state machine to a third isolator; and
a third receiver that outputs the second ON signal following the reception of the first state signal and the second state signal by the third isolator, and outputs the first ON signal after the voltage between the drain and the source decreases.

### (Appendix B10)

The method for controlling a semiconductor device according to Appendix B9, in which
the first state machine outputs a third state signal for outputting the first OFF signal and the second OFF signal on the basis of the first pulse signal, the second pulse signal, the third pulse signal, and the fourth pulse signal,
the third transmitter transmits the second state signal and the third state signal output from the first state machine to the third isolator, and
the third receiver outputs the first OFF signal following the reception of the second state signal and the third state signal by the third isolator, and then outputs the second OFF signal.

### (Appendix B11)

The method for controlling a semiconductor device according to Appendix B2,
the controller including:
a GDU that outputs the first ON signal to the first gate and outputs the second ON signal to the second gate; and
an MCU that outputs a fifth pulse signal for outputting at least one of the first ON signal and the second ON signal to the GDU, in which
when the first gate and the second gate are simultaneously controlled:
in the step of turning on the second gate,
the MCU drives the GDU by outputting the fifth pulse signal to the GDU in order to cause the GDU to output the second ON signal; and
in the step of turning on the first gate,
the MCU outputs the fifth pulse signal to the GDU after the voltage between the drain and the source decreases in order to cause the GDU to output the first ON signal.

### (Appendix B12)

The method for controlling a semiconductor device according to Appendix B11, the method further including:
a step of the MCU outputting, to the GDU, a sixth pulse signal for causing the GDU to output at least one of a first OFF signal for turning off the first gate and a second OFF signal for turning off the second gate in order to cause the GDU to turn off the first gate; and
a step of the MCU causing the GDU to output the second OFF signal by outputting, after the first gate is turned off, the sixth pulse signal to the GDU in order to cause the GDU to turn off the second gate.

### (Appendix B13)

The method for controlling a semiconductor device according to Appendix B12, in which
the GDU includes:
a fourth transmitter that transmits the fifth pulse signal output from the MCU to a fourth isolator;
a fourth receiver that outputs a first control signal following the reception of the fifth pulse signal by the fourth isolator; and
a second state machine that outputs the second ON signal by receiving the first control signal, and outputs the first ON signal after the voltage between the drain and the source decreases.

### (Appendix B14)

The method for controlling a semiconductor device according to Appendix B13, in which
the fourth transmitter transmits the sixth pulse signal output from the MCU to the fourth isolator,
the fourth receiver outputs a second control signal following the reception of the sixth pulse signal by the fourth isolator, and
the second state machine outputs the first OFF signal by receiving the second control signal, and then outputs the second OFF signal.

### (Appendix B15)

The method for controlling a semiconductor device according to Appendix B14, in which
the MCU outputs a seventh pulse signal, and
the GDU includes:
a fifth transmitter that transmits the seventh pulse signal output from the MCU to a fifth isolator;
a fifth receiver that outputs a first adjustment signal following the reception of the seventh pulse signal by the fifth isolator; and
a register that adjusts timings when the second state machine outputs the second ON signal following the reception of the first adjustment signal, and when the second state machine outputs the first ON signal after the voltage between the drain and the source decreases.

### (Appendix B16)

The method for controlling a semiconductor device according to Appendix B15, in which
the MCU outputs an eighth pulse signal,
the fifth transmitter transmits the eighth pulse signal output from the MCU to the fifth isolator,
the fifth receiver outputs a second adjustment signal following the reception of the eighth pulse signal by the fifth isolator, and
the register adjusts a timing when the second OFF signal is output after the second state machine outputs the first OFF signal following the reception of the second adjustment signal.

### (Appendix B17)

The method for controlling a semiconductor device according to Appendix B14, in which
the GDU includes an ADC that outputs a first digital value for adjusting timings when the second state machine outputs the second ON signal following the reception of a first voltage value from the outside, and when the second state machine outputs the first ON signal after the voltage between the drain and the source decreases.

### (Appendix B18)

The method for controlling a semiconductor device according to Appendix B17, in which
the ADC outputs a second digital value for adjusting timings when the second state machine outputs the first OFF signal following the reception of a second voltage value from the outside, and then when the second state machine outputs the second OFF signal.

What is claimed is:

1. A semiconductor device comprising:
a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET,
wherein the controller controls the first gate in a state where the second gate is turned on.

2. The semiconductor device according to claim 1, wherein the controller:
outputs a first ON signal for turning on the first gate and a second ON signal for turning on the second gate; and
when turning on the first gate and the second gate, controls such that the second gate is turned on by outputting the second ON signal, and the first gate is turned on by outputting the first ON signal after a voltage between the drain and the source decreases.

3. The semiconductor device according to claim 2, wherein the controller turns on the first gate by outputting the first ON signal after the voltage between the drain and the source decreases.

4. The semiconductor device according to claim 2, wherein the controller:
outputs a first OFF signal for turning off the first gate and a second OFF signal for turning off the second gate; and
when turning off the first gate and the second gate,
controls such that the first gate is turned off by outputting the first OFF signal, and then the second gate is turned off by outputting the second OFF signal.

5. The semiconductor device according to claim 2, the controller including:
a GDU that outputs the first ON signal to the first gate and outputs the second ON signal to the second gate; and
an MCU that outputs a first pulse signal for causing the GDU to output the first ON signal to the GDU and outputs a second pulse signal for causing the GDU to output the second ON signal to the GDU,
wherein when the first gate and the second gate are individually controlled,
the MCU:
causes the GDU to output the second ON signal by outputting the second pulse signal to the GDU; and
causes the GDU to output the first ON signal by outputting the first pulse signal to the GDU after the voltage between the drain and the source decreases.

6. The semiconductor device according to claim 5, wherein the GDU outputs a first OFF signal for turning off the first gate to the first gate and outputs a second OFF signal for turning off the second gate to the second gate, and
wherein the MCU outputs, to the GDU, a third pulse signal for causing the GDU to output the first OFF signal, and then outputs, to the GDU, a fourth pulse signal for causing the GDU to output the second OFF signal.

7. The semiconductor device according to claim 6, wherein the GDU includes:
a first transmitter that transmits the first pulse signal output from the MCU to a first isolator;
a first receiver that outputs the first ON signal following the reception of the first pulse signal by the first isolator;
a second transmitter that transmits the second pulse signal output from the MCU to a second isolator; and
a second receiver that outputs the second ON signal following the reception of the second pulse signal by the second isolator.

8. The semiconductor device according to claim 7, wherein the first transmitter transmits the third pulse signal output from the MCU to the first isolator,
wherein the first receiver outputs the first OFF signal following the reception of the third pulse signal by the first isolator,
wherein the second transmitter transmits the fourth pulse signal output from the MCU to the second isolator, and
wherein the second receiver outputs the second OFF signal following the reception of the fourth pulse signal by the second isolator.

9. The semiconductor device according to claim 6, wherein the GDU includes:
a first state machine that, based on the first pulse signal, the second pulse signal, the third pulse signal, and the fourth pulse signal, outputs a first state signal for outputting the first ON signal and the second ON signal and outputs a second state signal for outputting the first OFF signal and the second ON signal;
a third transmitter that transmits the first state signal and the second state signal output from the first state machine to a third isolator; and
a third receiver that outputs the second ON signal following the reception of the first state signal and the second state signal by the third isolator, and outputs the first ON signal after the voltage between the drain and the source decreases.

10. The semiconductor device according to claim 9, wherein the first state machine outputs a third state signal for outputting the first OFF signal and the second OFF signal on the basis of the first pulse signal, the second pulse signal, the third pulse signal, and the fourth pulse signal,
wherein the third transmitter transmits the second state signal and the third state signal output from the first state machine to the third isolator, and
wherein the third receiver outputs the first OFF signal following the reception of the second state signal and the third state signal by the third isolator, and then outputs the second OFF signal.

11. The semiconductor device according to claim 2, the controller including:
a GDU that outputs the first ON signal to the first gate and outputs the second ON signal to the second gate; and
an MCU that outputs, to the GDU, a fifth pulse signal for causing the GDU to output at least one of the first ON signal and the second ON signal,
wherein when the first gate and the second gate are simultaneously controlled,
the MCU drives the GDU by outputting the fifth pulse signal to the GDU, and
the GDU outputs the second ON signal, and outputs the first ON signal after the voltage between the drain and the source decreases.

12. The semiconductor device according to claim 11, wherein the GDU outputs a first OFF signal for turning off the first gate to the first gate and outputs a second OFF signal for turning off the second gate to the second gate,
wherein the MCU drives the GDU by outputting, to the GDU, a sixth pulse signal for causing the GDU to output at least one of the first OFF signal and the second OFF signal, and
wherein the GDU outputs the first OFF signal, and then outputs the second OFF signal.

13. The semiconductor device according to claim 12, wherein the GDU includes:
a fourth transmitter that transmits the fifth pulse signal output from the MCU to a fourth isolator;
a fourth receiver that outputs a first control signal following the reception of the fifth pulse signal by the fourth isolator; and
a second state machine that outputs the second ON signal by receiving the first control signal, and outputs the first ON signal after the voltage between the drain and the source decreases.

14. The semiconductor device according to claim 13, wherein the fourth transmitter transmits the sixth pulse signal output from the MCU to the fourth isolator,
wherein the fourth receiver outputs a second control signal following the reception of the sixth pulse signal by the fourth isolator, and
wherein the second state machine outputs the first OFF signal by receiving the second control signal, and then outputs the second OFF signal.

15. The semiconductor device according to claim 14, wherein the MCU outputs a seventh pulse signal, and
wherein the GDU includes:
a fifth transmitter that transmits the seventh pulse signal output from the MCU to a fifth isolator;
a fifth receiver that outputs a first adjustment signal following the reception of the seventh pulse signal by the fifth isolator; and
a register that adjusts timings when the second state machine outputs the second ON signal following the reception of the first adjustment signal, and when the second state machine outputs the first ON signal after the voltage between the drain and the source decreases.

16. The semiconductor device according to claim 15, wherein the MCU outputs an eighth pulse signal,
wherein the fifth transmitter transmits the eighth pulse signal output from the MCU to the fifth isolator,
wherein the fifth receiver outputs a second adjustment signal following the reception of the eighth pulse signal by the fifth isolator, and
wherein the register adjusts timings when the second state machine outputs the first OFF signal following the reception of the second adjustment signal, and then when the second state machine outputs the second OFF signal.

17. The semiconductor device according to claim 14, wherein the GDU includes an ADC that outputs a first digital value for adjusting timings when the second state machine outputs the second ON signal following the reception of a first voltage value from the outside, and when the second state machine outputs the first ON signal after the voltage between the drain and the source decreases.

18. The semiconductor device according to claim 17, wherein the ADC outputs a second digital value for adjusting timings when the second state machine outputs the first OFF signal following the reception of a second voltage value from the outside, and then when the second state machine outputs the second OFF signal.

19. The semiconductor device according to claim 1, wherein the controller:
outputs a first OFF signal for turning off the first gate and a second OFF signal for turning off the second gate; and
when turning off the first gate and the second gate, controls such that the first gate is turned off by outputting the first OFF signal, and then the second gate is turned off by outputting the second OFF signal.

20. A method for controlling a semiconductor device, the semiconductor device including a controller that, in an element that connects a collector of an IGBT, a drain of a MOSFET, and a cathode of a diode and connects an emitter of the IGBT, a source of the MOSFET, and an anode of the diode, controls a first gate that is a gate of the IGBT and a second gate that is a gate of the MOSFET,
the method comprising a step of controlling the first gate in a state where the second gate is turned on.
